(19) United States
(12) Patent Application Publication
(10) Pub. No.: US 2002/0110252 A1
(43) Pub. Date: Aug. 15, 2002

(54) Microphone assembly

(76) Inventor: Chang-Ming Liu, Taichung City (TW)

Correspondence Address: PILLSBURY WINTHROP, LLP, P.O. BOX 10500, MCLEAN, VA, 22102, US

(21) Appl. No.: 09/780,338

(22) Filed: Feb. 12, 2001

(51) Int. Cl. H03F 21/00; H04R 3/00

(52) U.S. Cl. 381/120; 381/91; 381/92; 381/122; 381/123; 381/361

(57) ABSTRACT

A microphone assembly includes a main plug unit, a voice-activated microphone unit, a throat-vibration-activated microphone unit, and a control circuit coupled to the main plug unit, the voice-activated microphone unit and the throat-vibration-activated microphone unit. The control circuit is operable between a first state, wherein the main plug unit is coupled to the voice-activated microphone unit and is disconnected from the throat-vibration-activated microphone unit, and a second state, wherein the main plug unit is disconnected from the voice-activated microphone unit and is coupled to the throat-vibration-activated microphone unit.

### BACKGROUND OF THE INVENTION

1. Field of the Invention

The invention relates to a microphone assembly, more particularly to a microphone assembly that is operable so that one of a voice-activated microphone unit and a throat-vibration activated microphone unit can be selected for use.

2. Description of the Related Art

A microphone is used for voice-to-signal conversion and is widely used in a number of applications, such as with a mobile telephone. Generally, there are two kinds of microphones, such as a voice-activated microphone and a throat-vibration-activated microphone. The voice-activated microphone, such as a condenser microphone, utilizes air as a transmitting medium and receives sound waves with different timbres. However, the voice-activated microphone easily picks up surrounding noise from an environment where the user is located, thereby resulting in a poor output quality. On the other hand, the throat-vibration-activated microphone utilizes a vibration-transmitting device that contacts the user's throat to receive vibrating waves therefrom when the user is talking. However, as the throat-vibration-activated microphone is usually provided on a C-shaped ring to be worn around the user's neck, use is inconvenient, and besides, the user will feel uncomfortable after prolonged use.

### SUMMARY OF THE INVENTION

Therefore, the object of the present invention is to provide a microphone assembly that is operable so that one of a voice-activated microphone unit and a throat-vibration activated microphone unit to can be selected for use.

According to the present invention, a microphone assembly comprises:

a main plug unit;

a voice-activated microphone unit;

a throat-vibration-activated microphone unit; and

a control circuit coupled to the main plug unit, the voice-activated microphone unit and the throat-vibration-activated microphone unit, the control circuit being operable between a first state, wherein the main plug unit is coupled to the voice-activated microphone unit and is disconnected from the throat-vibration-activated microphone unit, and a second state, wherein the main plug unit is disconnected from the voice-activated microphone unit and is coupled to the throat-vibration-activated microphone unit.

### BRIEF DESCRIPTION OF THE DRAWINGS

Other features and advantages of the present invention will become apparent in the following detailed description of the preferred embodiments with reference to the accompanying drawings, of which:

FIG. 1 is an exploded perspective view showing the first preferred embodiment of a microphone assembly according to the present invention;

FIG. 2 is a schematic circuit block diagram illustrating the first preferred embodiment; and

FIG. 3 is a schematic circuit block diagram showing the second preferred embodiment of a microphone assembly according to the present invention.

### DETAILED DESCRIPTION OF THE PREFERRED EMBODIMENTS

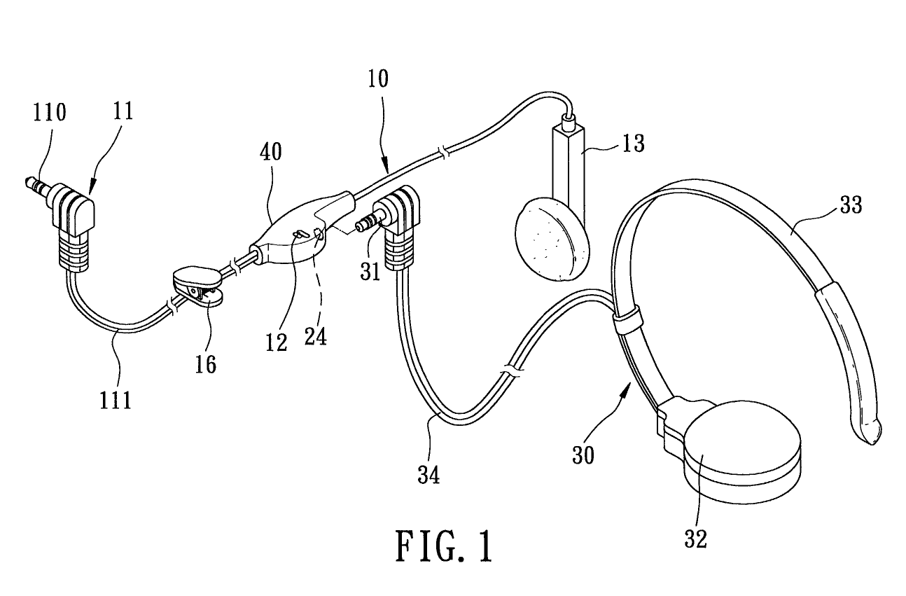

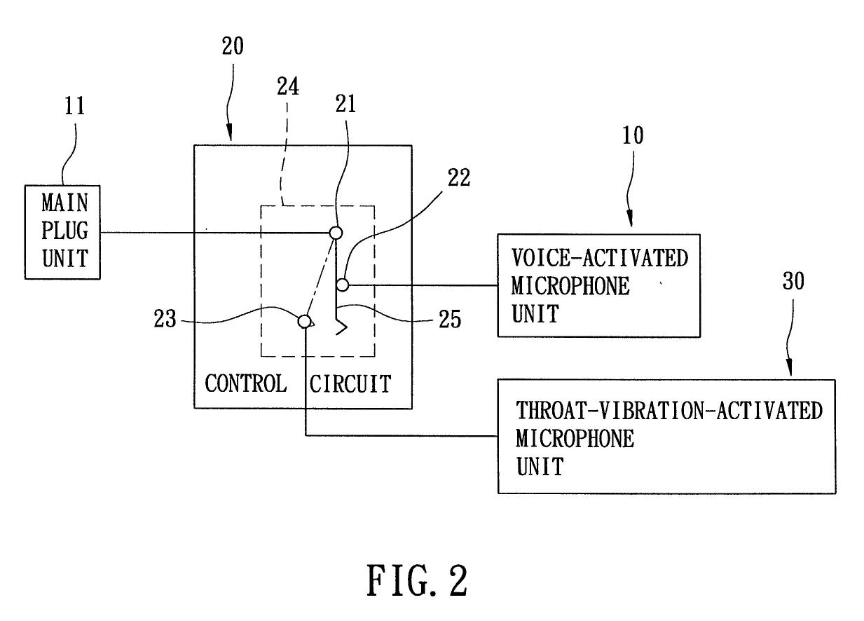

Referring to FIGS. 1 and 2, according to the first preferred embodiment of the present invention, a microphone assembly is shown to include a main plug unit 11, a voice-activated microphone unit 10, a throat-vibration-activated microphone unit 30, and a control circuit 20. The main plug unit 11 includes a signal plug 110 adapted to be inserted into a signal jack (not shown) of a cellular phone, and a connecting wire 111 coupled electrically to the signal plug 110. The voice-activated microphone unit 10 includes a condenser microphone 12 provided on a circuit board (not shown) that is received in a housing 40, and an ear phone 13. A clip 16 is provided on the connecting wire 111, and is adapted to be attached on a piece of clothing of the user such that the condenser microphone 12 is kept closely adjacent to the mouth of the user.

The throat-vibration-activated microphone unit 30 includes a vibration-transmitting device 32 provided on an end portion of a resilient C-shaped ring 33 that is adapted to be worn on the user's neck such that the vibration-transmitting device 32 is adapted to contact the user's throat and to sense vibrating waves therefrom when the user is talking.

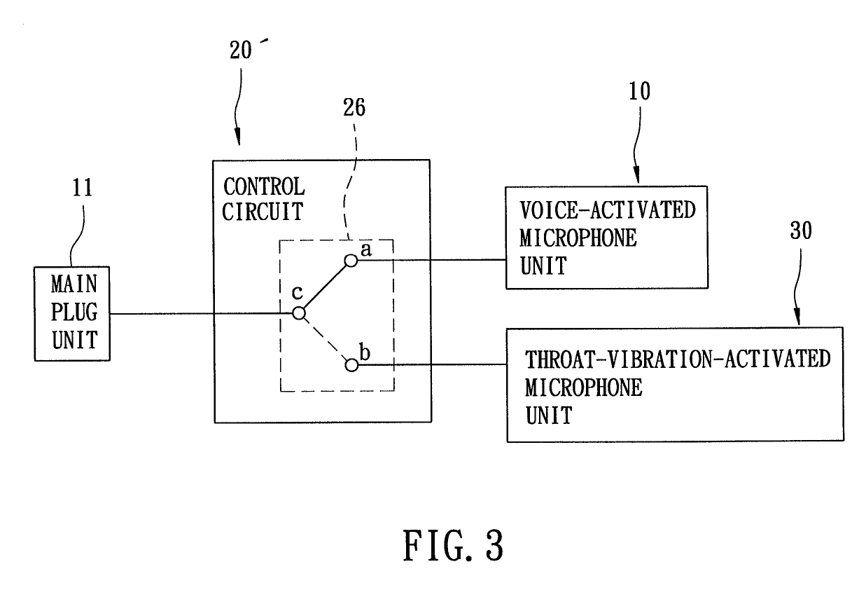

The control circuit 20 is coupled to the main plug unit 11 via the connecting wire 111, the voice-activated microphone unit 10 and the throat-vibration-activated microphone unit 30. The control circuit 20 is operable between a first state, wherein the main plug unit 11 is coupled to the voice-activated microphone unit 10 and is disconnected from the throat-vibration-activated microphone unit 30, and a second state, wherein the main plug unit 11 is disconnected from the voice-activated microphone unit 10 and is coupled to the throat-vibration-activated microphone unit 30. In this embodiment, the throat-vibration-activated microphone unit 30 further includes a microphone plug 31 coupled to the vibration-transmitting device 32 via a connecting wire 34, and the control circuit 30 includes a microphone jack 24 coupled removably to the microphone plug 31 of the throat-vibration-activated microphone unit 30. The microphone jack 24, which is conventional in construction, has a first node 21 coupled to the main plug unit 11, a second node 22 coupled to the voice-activated microphone unit 10, a third node 23 for connection to the microphone plug 31 of the throat-vibration-activated microphone unit 30, and a resilient conductive plate 25 coupled to and extending from the first node 21. The conductive plate 25 is associated operably with the microphone plug 31 so as to move from the first state, wherein the conductive plate 25 contacts the second node 22, to the second state, wherein the conductive plate 25 contacts the third node 23, when the microphone plug 31 is inserted into the microphone jack 24. FIG. 3 illustrates the second preferred embodiment of the present invention, which is a modification of the first preferred embodiment. Unlike the previous embodiment, the control circuit 20′ includes a switch unit 26 having a first switch contact (a) coupled to the voice-activated microphone unit 10, a second switch contact (b) coupled to the throat-vibration-activated microphone unit 30, and a movable switch contact (c) coupled to the main plug unit 11 and operable so as to connect the plug unit 11 to a selected one of the first and second switch contacts (a, b). Like previous embodiment, the throat-vibration-activated microphone unit 30 can be connected to the control circuit 20′ via a plug-and-jack connection.

It is noted that, due to the presence of the control circuit 20, 20′, the user is able to select the voice-activated microphone unit 10 for use when the user's environment is quiet, or the throat-vibration-activated microphone unit 30 for use when the user's environment is noisy. While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

I claim:

1. A microphone assembly comprising:
a main plug unit;
a voice-activated microphone unit;
a throat-vibration-activated microphone unit; and
a control circuit coupled to said main plug unit, said voice-activated microphone unit and said throat-vibration-activated microphone unit, said control circuit being operable between a first state, wherein said main plug unit is coupled to said voice-activated microphone unit and is disconnected from said throat-vibration-activated microphone unit, and a second state, wherein said main plug unit is disconnected from said voice-activated microphone unit and is coupled to said throat-vibration-activated microphone unit.

2. The microphone assembly of claim 1, wherein said throat-vibration-activated microphone unit includes a microphone plug, and said control circuit includes a microphone jack coupled removably to said microphone plug and having a first node coupled to said main plug unit, a second node coupled to said voice-activated microphone unit, a third node for connection to said microphone plug of said throat-vibration-activated microphone unit, and a resilient conductive plate coupled to and extending from said first node, said conductive plate being associated operably with said microphone plug so as to move from the first state, wherein said conductive plate contacts said second node, to the second state, wherein said conductive plate contacts said third node, when said microphone plug is inserted into said microphone jack.

3. The microphone assembly of claim 1, wherein said control circuit includes a switch unit having a first switch contact coupled to said voice-activated microphone unit, a second switch contact coupled to said throat-vibration-activated microphone unit, and a movable switch contact coupled to said main plug unit and operable so as to connect said main plug unit to a selected one of said first and second switch contacts.
